(19) United States
(12) Patent Application Publication
(10) Pub. No.: US 2023/0283866 A1
(43) Pub. Date: Sep. 7, 2023

(54) IMAGING DEVICE

(71) Applicant: HAMAMATSU PHOTONICS K.K., Hamamatsu-shi, Shizuoka (JP)

(72) Inventor: Mitsuhito MASE, Hamamatsu-shi, Shizuoka (JP)

(73) Assignee: HAMAMATSU PHOTONICS K.K., Hamamatsu-shi, Shizuoka (JP)

(21) Appl. No.: 18/015,447

(22) PCT Filed: Jul. 7, 2021
(86) PCT No.: PCT/JP2021/025650

§ 371 Date: Jan. 10, 2023

(30) Foreign Application Priority Data
Jul. 31, 2020 (JP) 2020-130506

(51) Int. Cl. H04N 23/13; H04N 25/77; H04N 25/131; H04N 23/11; H04N 25/78; H01L 27/146; G01S 17/10

(52) U.S. Cl. CPC H04N 23/13; H04N 25/77; H04N 25/131; H04N 23/11; H04N 25/78; H01L 27/1462; H01L 27/14621; H01L 27/14625; H01L 27/14627; H01L 27/14645; H01L 27/14649; G01S 17/10

(57) ABSTRACT

An imaging device includes a first optical sensor, and a second optical sensor disposed on the side opposite to the light incidence side with respect to the first optical sensor and bonded to the first optical sensor. The first optical sensor includes a plurality of first pixels disposed two-dimensionally. The second optical sensor includes a plurality of second pixels disposed two-dimensionally. Each of the plurality of first pixels includes an embedded photodiode that generates charge in response to incidence of light in a first wavelength band. Each of the plurality of second pixels includes a charge generation region that generates charge in response to incidence of the light in a second wavelength band, a charge collection region to which the charge is transferred, a photogate electrode that attracts the charge, and a transfer gate electrode that transfers the charge to the charge collection region.

### TECHNICAL FIELD

The present disclosure relates to an imaging device.

### BACKGROUND ART

An imaging device for acquiring a distance image of a target object (an image including information on a distance to the target object), which includes an image sensor that detects visible light and a distance measurement sensor that detects near-infrared light is known (see, for example, Patent Literature 1). In such an imaging device, the distance measurement sensor may be disposed on the side opposite to the light incidence side with respect to the image sensor in a light incidence direction.

### CITATION LIST

### Patent Literature

[Patent Literature 1] Japanese Unexamined Patent Publication No. 2017-112169

### SUMMARY OF INVENTION

### Technical Problem

In the imaging device as described above, for example, from the viewpoint of widening a distance measurement range, it is important how the sensitivity can be improved in an optical sensor disposed on the side opposite to the light incidence side in the light incidence direction (hereinafter referred to as an “optical sensor” in a subsequent stage) between two optical sensors.

An object of the present disclosure is to provide an imaging device capable of improving the sensitivity of an optical sensor in a subsequent stage.

### Solution to Problem

An imaging device according to an aspect of the present disclosure includes a first optical sensor configured to detect light in a first wavelength band; and a second optical sensor disposed on the side opposite to the light incidence side with respect to the first optical sensor in an incidence direction of light, bonded to the first optical sensor, and configured to detect light in a second wavelength band on a longer wavelength side relative to the first wavelength band, wherein the first optical sensor includes a plurality of first pixels disposed two-dimensionally along a first surface intersecting with the incidence direction, the second optical sensor includes a plurality of second pixels disposed two-dimensionally along a second surface intersecting with the incidence direction, each of the plurality of first pixels includes an embedded photodiode configured to generate charge in response to incidence of the light in the first wavelength band, and each of the plurality of second pixels includes a charge generation region configured to generate charge in response to the incidence of the light in the second wavelength band; a charge collection region to which the charge generated in the charge generation region is transferred; a photogate electrode configured to attract the charge generated in the charge generation region; and a transfer gate electrode configured to transfer the charge attracted by the photogate electrode to the charge collection region.

In this imaging device, in the second optical sensor that is an optical sensor in the subsequent stage, each of the plurality of second pixels may include the charge generation region, the charge collection regions, the photogate electrode, and the transfer gate electrodes. Accordingly, in each of the plurality of second pixels, the charge generated in the charge generation region is attracted by the photogate electrode, and the attracted charge is transferred to the charge collection region by the transfer gate electrode. Therefore, even when the charge generated in the charge generation region is small in amount, the charge is transferred to the charge collection region at high speed and reliably. Therefore, with this imaging device, it is possible to improve the sensitivity of the optical sensor in the subsequent stage.

In the imaging device according to the aspect of the present disclosure, a size of each of the plurality of second pixels when viewed in the incidence direction may be larger than a size of each of the plurality of first pixels when viewed in the incidence direction. This makes it possible to improve the sensitivity of each of the plurality of second pixels, for example, as compared to a case in which the size of each of the plurality of second pixels is the same as the size of each of the plurality of first pixels.

The imaging device according to the aspect of the present disclosure may further include: a plurality of lenses disposed to correspond to the plurality of first pixels and the plurality of second pixels, on the light incidence side with respect to the first optical sensor in the incidence direction, and configured to condense the light in the first wavelength band and the light in the second wavelength band within the first optical sensor. Accordingly, the light in the second wavelength band is incident on each of the plurality of second pixels in a diverged state. In this case, because a size of each of the plurality of second pixels is larger than a size of each of the plurality of first pixels, it is possible for each of the plurality of second pixels to efficiently receive the light in the second wavelength band.

The imaging device according to the aspect of the present disclosure may further include a plurality of texture structures disposed to correspond to the plurality of second pixels, on the light incidence side with respect to the first optical sensor in the incidence direction, wherein the first optical sensor may further include a reflection portion surrounding a region corresponding to each of the plurality of texture structures when viewed in the incidence direction. Accordingly, the light in the second wavelength band incident on the first optical sensor at various angles while reflection is suppressed in the texture structure is incident on the second pixel at various angles while being reflected by the reflection portion. Further, a size of the second pixel when viewed in the incidence direction is larger than a size of the first pixel when viewed in the incidence direction. Therefore, an optical path of the light in the second wavelength band becomes longer in the second pixel, and the light in the second wavelength band is easily absorbed in the charge generation region of the second pixel. This makes it possible for each of the plurality of second pixels to efficiently receive the light in the second wavelength band.

In the imaging device according to the aspect of the present disclosure, the first optical sensor may further include a plurality of light passage portions disposed two-dimensionally along the first surface, and each of the plurality of second pixels may overlap at least one of the plurality of light passage portions when viewed in the incidence direction. This makes it possible to cause the light in the second wavelength band to be efficiently incident on the second pixel via the light passage portion.

In the imaging device according to the aspect of the present disclosure, each of the plurality of light passage portions may include a waveguide structure. This makes it possible to cause the light in the second wavelength band to be more efficiently incident on the second pixel via the waveguide structure.

In the imaging device according to the aspect of the present disclosure, the charge generation region may include an avalanche multiplication region. This makes it possible to further improve the sensitivity of the second optical sensor because the charge generated in the charge generation region is avalanche-multiplied.

The imaging device according to the aspect of the present disclosure may further include: a plurality of color filters disposed to correspond to the plurality of first pixels, on the light incidence side with respect to the first optical sensor in the incidence direction, and configured to selectively transmit visible light, the visible light being the light in the first wavelength band. This makes it possible to acquire an image of a target object using the visible light on the basis of a signal output from the first optical sensor.

The imaging device according to the aspect of the present disclosure may further include a band pass filter disposed between the first optical sensor and the second optical sensor and configured to selectively transmit near-infrared light, the near-infrared light being the light in the second wavelength band. This makes it possible to accurately detect the near-infrared light in the second optical sensor.

The imaging device according to the aspect of the present disclosure may further include a plurality of plasmon filters disposed to correspond to the plurality of second pixels, on the light incidence side with respect to the first optical sensor in the incidence direction, and configured to selectively transmit near-infrared light, the near-infrared light being the light in the second wavelength band. This makes it possible to accurately detect the near-infrared light in the second optical sensor.

In the imaging device according to the aspect of the present disclosure, the charge collection region may overlap one of the plurality of first pixels when viewed in the incidence direction. This makes it possible to suppress the occurrence of parasitic sensitivity caused by incidence of the light in the second wavelength band on each charge collection region.

In the imaging device according to the aspect of the present disclosure, the embedded photodiode may be formed of silicon, and the charge generation region and the charge collection region may be made of silicon. This makes it possible to easily manufacture the second optical sensor.

In the imaging device according to the aspect of the present disclosure, the embedded photodiode may be formed of silicon, and the charge generation region and the charge collection region may be made of germanium. This makes it possible to further improve the sensitivity of the second optical sensor to the near-infrared light, for example.

In the imaging device according to the aspect of the present disclosure, the first optical sensor may further include a first wiring layer disposed on the side opposite to the light incidence side with respect to the plurality of first pixels in the incidence direction, the second optical sensor may further include a second wiring layer disposed on the light incidence side with respect to the plurality of second pixels in the incidence direction, and the second wiring layer may be electrically and physically connected to the first wiring layer. This makes it possible to achieve integration of a wiring structure in the imaging device.

In the imaging device according to the aspect of the present disclosure, the first optical sensor may further include a signal readout unit, and the signal readout unit may read a first signal from each of the plurality of first pixels and read a second signal from each of the plurality of second pixels. This makes it possible to share the signal readout unit.

In the imaging device according to the aspect of the present disclosure, the signal readout unit may cause charge to be accumulated in each of the plurality of first pixels and read the second signal from each of the plurality of second pixels in first periods among alternately repeated first and second periods, and may cause charge to be accumulated in each of the plurality of second pixels and read the first signal from each of the plurality of first pixels in the second periods. Accordingly, when the imaging device is used together with the light source that emits the light in the second wavelength band, the light in the second wavelength band is prevented from being emitted from the light source in the first period in which the charge is accumulated in each of the plurality of first pixels. This makes it possible to prevent the first signal output from each of the plurality of first pixels from being influenced by the light in the second wavelength band.

In the imaging device according to the aspect of the present disclosure, the signal readout unit may cause charge to be accumulated in each of the plurality of first pixels and charge to be accumulated in each of the plurality of second pixels in first periods among alternately repeated first and second periods, and read the first signal from each of the plurality of first pixels and the second signal from each of the plurality of second pixels in the second periods. This makes it possible to associate distance information acquired by the second optical sensor in a subsequent stage with the image acquired by the first optical sensor in a preceding stage easily and accurately not only in terms of position but also in terms of time.

### Advantageous Effects of Invention

According to the present disclosure, it is possible to provide an imaging device capable of improving the sensitivity of the optical sensor in the subsequent stage.

### BRIEF DESCRIPTION OF DRAWINGS

FIG. 1 is a side view of an imaging device according to a first embodiment.

FIG. 2 is a cross-sectional view of a portion of the imaging device illustrated in FIG. 1.

FIG. 3 is a plan view (a) of a first pixel portion of a first optical sensor illustrated in FIG. 1 and a plan view (b) of a second pixel portion of a second optical sensor illustrated in FIG. 1.

FIG. 4 is a cross-sectional view of a part of an imaging device of a modification example.

FIG. 5 is a cross-sectional view of a part of an imaging device according to a second embodiment.

FIG. 6 is a cross-sectional view of a part of an imaging device according to a third embodiment.

FIG. 7 is a cross-sectional view of a part of an imaging device according to a fourth embodiment.

FIG. 8 is a cross-sectional view of a part of an imaging device according to a fifth embodiment.

FIG. 9 is a plan view (a) of a first pixel portion of a first optical sensor illustrated in FIG. 8 and a plan view (b) of a second pixel portion of a second optical sensor illustrated in FIG. 8.

FIG. 10 is a cross-sectional view of a part of an imaging device according to a sixth embodiment.

FIG. 11 is a cross-sectional view of a part of an imaging device according to a seventh embodiment.

FIG. 12 is a plan view (a) of a first pixel portion of a modification example and a plan view (b) of a second pixel portion of a second optical sensor of the modification example.

FIG. 13 is a plan view (a) of a first pixel portion of a modification example and a plan view (b) of a second pixel portion of a second optical sensor of the modification example.

FIG. 14 is a plan view (a) of a first pixel portion of a modification example and a plan view (b) of a second pixel portion of a second optical sensor of the modification example.

### DESCRIPTION OF EMBODIMENTS

Hereinafter, embodiments of the present disclosure will be described in detail with reference to the drawings. In each figure, the same or equivalent portions are denoted by the same reference signs, and repeated description is omitted.

### First Embodiment

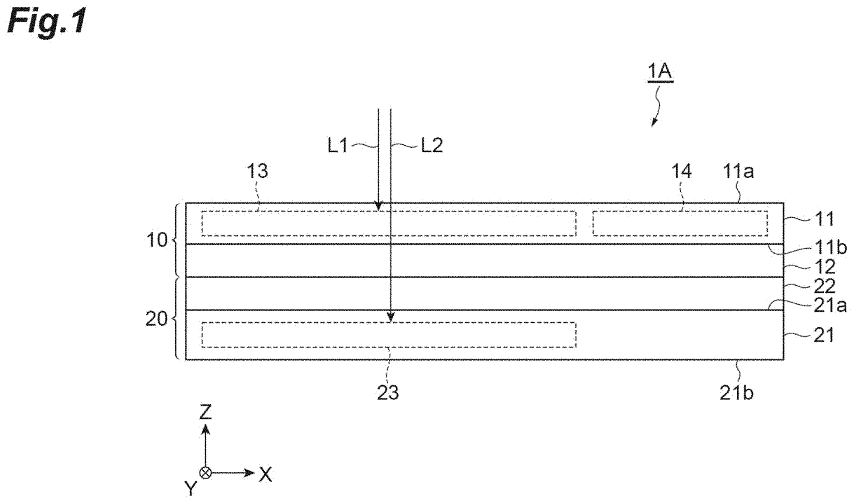

As illustrated in FIG. 1, an imaging device 1A includes a first optical sensor 10 and a second optical sensor 20. The first optical sensor 10 detects visible light (light in a first wavelength band) L1. The second optical sensor 20 detects near-infrared light (light in a second wavelength band) L2 incident from the same side as the visible light L1. The second optical sensor 20 is disposed on the side opposite to the light incidence side with respect to the first optical sensor 10 in an incidence direction of light (the visible light L1 and near-infrared light L2), and is bonded to the first optical sensor 10. As an example, the second optical sensor 20 is bonded to the first optical sensor 10 by resin bonding or direct bonding. Hereinafter, an incidence direction of light is referred to as a Z direction, one direction perpendicular to the Z direction is referred to as an X direction, and a direction perpendicular to both the Z direction and the X direction is referred to as a Y direction.

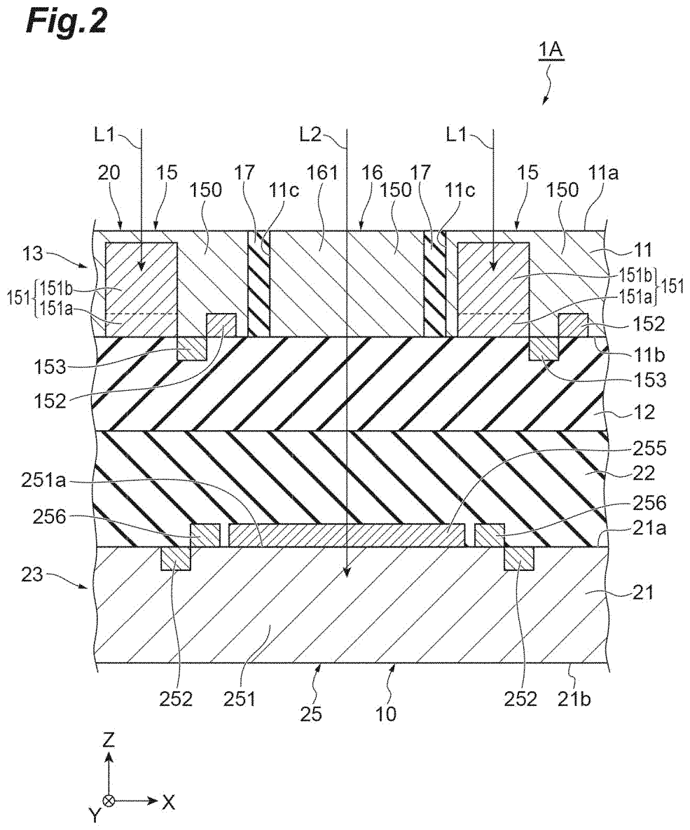

The first optical sensor 10 includes a first semiconductor layer 11 and a first wiring layer 12. The first semiconductor layer 11 includes a first pixel portion 13 and a signal readout unit 14. A thickness of the first semiconductor layer 11 is, for example, about 3 to 10 μm. The first wiring layer 12 is disposed on a surface 11b between a surface 11a on the light incidence side and the surface 11b on the opposite side in the first semiconductor layer 11. That is, the first wiring layer 12 is disposed on the side opposite to the light incidence side with respect to the plurality of first pixels 15 (see FIG. 2) in the Z direction. The first pixel portion 13 is electrically connected to the signal readout unit 14 via the first wiring layer 12. The signal readout unit 14 includes a voltage signal generation circuit, a CMOS readout circuit, a vertical scanning circuit, a column circuit, a horizontal scanning circuit, an amplifier, a timing generation circuit, and the like.

The second optical sensor 20 includes a second semiconductor layer 21 and a second wiring layer 22. The second semiconductor layer 21 includes a second pixel portion 23. A thickness of the second semiconductor layer 21 is, for example, about 100 to 700 μm. The second wiring layer 22 is disposed on a surface 21a between the surface 21a on the light incidence side and a surface 21b on the side opposite to the light incidence side in the second semiconductor layer 21. That is, the second wiring layer 22 is disposed on the light incidence side with respect to the plurality of second pixels 25 (see FIG. 2) in the Z direction. The second wiring layer 22 is electrically and physically connected to the first wiring layer 12. The second pixel portion 23 is electrically connected to the signal readout unit 14 via the second wiring layer 22 and the first wiring layer 12.

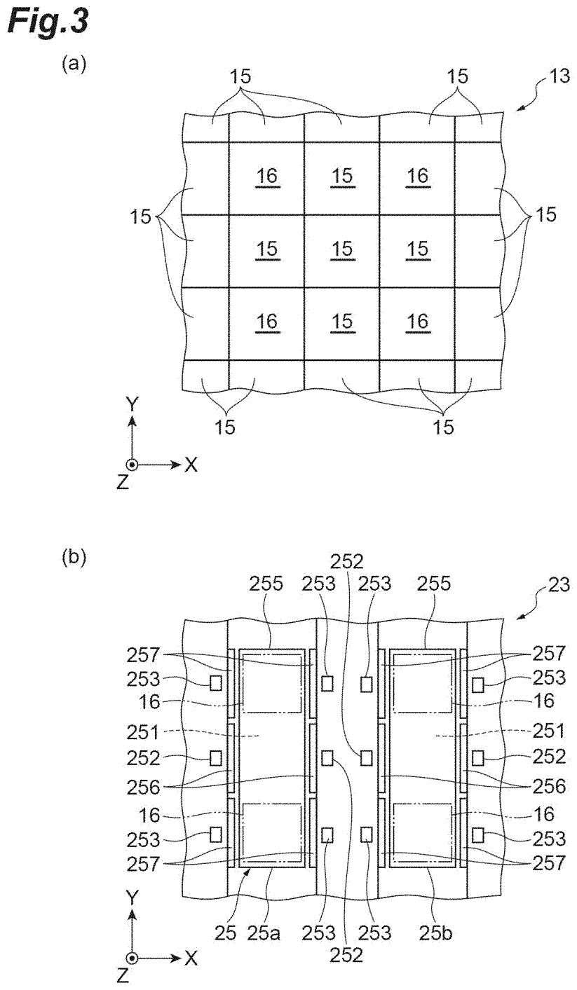

As illustrated in FIG. 2, the first pixel portion 13 includes a plurality of first pixels 15 and a plurality of light passage portions 16. The plurality of first pixels 15 and the plurality of light passage portions 16 are disposed two-dimensionally along the surface (a first surface intersecting an incidence direction) 11a in the first semiconductor layer 11. As an example, as illustrated in (a) of FIG. 3, the plurality of first pixels 15 and the plurality of light passage portions 16 are disposed in a matrix form such that the plurality of light passage portions 16 are disposed via the first pixels 15 in one column and are disposed via the first pixels 15 in one row. A shape of each of the first pixels 15 and the light passage portions 16 when viewed in the Z direction is, for example, a square shape having one side whose length is about several μm. The plurality of first pixels 15 and the plurality of light passage portions 16 are disposed in a matrix form of 1000 rows and 1000 columns, for example.

As illustrated in FIG. 2, each first pixel 15 includes an embedded photodiode 151, a charge collection region 152, and a transfer gate electrode 153. The embedded photodiode 151 and the charge collection region 152 are formed by performing various processing (for example, etching, film formation, and impurity implantation) on a silicon substrate. That is, the embedded photodiode 151 and the charge collection region 152 are formed of silicon.

The embedded photodiode 151 is formed in a p-type semiconductor region 150 along the surface 11b. The embedded photodiode 151 includes a p-type semiconductor region 151a on the surface 11b side having an impurity concentration higher than that of the p-type semiconductor region 150, and an n-type semiconductor region 151b on the surface 11a side. A portion of the p-type semiconductor region 150 exists between the embedded photodiode 151 and the surface 11b. In the embedded photodiode 151, the p-type semiconductor region 151a and the n-type semiconductor region 151b form a pn junction. The embedded photodiode 151 functions as a photoelectric conversion region that generates charge in response to incidence of the visible light L1. The impurity concentration of the p-type semiconductor region 150 is, for example, about 1×10¹³ to 1×10¹⁶ cm⁻³. The impurity concentration of the p-type semiconductor region 151a of the embedded photodiode 151 is, for example, about 1×10¹⁶ to 1×10¹⁹ cm⁻³. The impurity concentration of the n-type semiconductor region 151b of the embedded photodiode 151 is, for example, about 1×10¹⁴ to 1×10¹⁷ cm⁻³.

The charge collection region 152 is formed in the p-type semiconductor region 150 along the surface 11b on one side of the embedded photodiode 151 in the X direction. The charge collection region 152 is an n-type semiconductor region having a higher impurity concentration than the n-type semiconductor region 151b of the embedded photodiode 151. The charge collection region 152 functions as a charge accumulation region to which the charge generated in the embedded photodiode 151 is transferred as signal charge. An impurity concentration of the charge collection region 152 is, for example, about 1×10¹⁸ to 1×10²⁰ cm⁻³.

The transfer gate electrode 153 is disposed on the surface 11b via an insulating film (not illustrated) to be positioned between the embedded photodiode 151 and the charge collection region 152 when viewed in the Z direction. The transfer gate electrode 153 is formed of a material (for example, polysilicon) having electrical conductivity and optical transparency to the near-infrared light L2. The transfer gate electrode 153 functions as an electrode that transfers the charge generated in the embedded photodiode 151 to the charge collection region 152.

The light passage portion 16 includes a waveguide structure 161. The waveguide structure 161 is configured by a portion of the p-type semiconductor region 150. That is, the light passage portion 16 differs from the first pixel 15 in that the light passage portion 16 does not include the embedded photodiode 151, the charge collection region 152, and the transfer gate electrode 153. The light passage portion 16 functions as a light transmission portion that transmits the near-infrared light L2. A light passage hole may be formed in the first semiconductor layer 11, instead of the waveguide structure 161.

A trench 11c is formed in the first semiconductor layer 11 to separate the first pixel 15 and the light passage portion 16 from each other. An insulating member 17 such as silicon oxide is disposed in the trench 11c. A metal member such as tungsten may be disposed in the trench 11c, instead of the insulating member 17.

As illustrated in FIGS. 2 and 3(b), the second pixel portion 23 includes a plurality of second pixels 25. The plurality of second pixels are disposed two-dimensionally along a surface (second surface intersecting the incidence direction) 21a in the second semiconductor layer 21. A shape of the second pixel 25 when viewed in the Z direction is, for example, a square having one side whose length is about ten and several μm. The plurality of second pixels 25 are disposed in a matrix form with 250 rows and 250 columns, for example.

Each second pixel 25 is configured of a first portion 25a and a second portion 25b that are adjacent in the X direction. Each of the first portion 25a and the second portion 25b includes a charge generation region 251, a pair of charge collection regions 252, two pairs of charge collection regions 253, a photogate electrode 255, a pair of transfer gate electrodes 256, and two pairs of transfer gate electrodes 257. The charge generation region 251, the pair of charge collection regions 252, and the two pairs of charge collection regions 253 are formed by performing various processing (for example, etching, film formation, and impurity implantation) on the silicon substrate. That is, the charge generation region 251, the pair of charge collection regions 252, and the two pairs of charge collection regions 253 are made of silicon.

The charge generation region 251 is a p-type semiconductor region. The charge generation region 251 functions as a photoelectric conversion region that generates charge in response to incidence of the near-infrared light L2. An impurity concentration of the charge generation region 251 is, for example, about 1×10¹³ to 1×10¹⁶ cm⁻³.

The near-infrared light L2 is transmitted through the first semiconductor layer 11, the first wiring layer 12, and the second wiring layer 22 and is incident on the charge generation region 251. The near-infrared light L2 can be transmitted through the first pixels 15 and the light passage portion 16 in the first semiconductor layer 11, but is particularly transmitted through the light passage portion 16 including the waveguide structure 161. Each of the first wiring layer 12 and the second wiring layer 22 may include a waveguide structure or a light passage hole overlapping each light passage portion 16 when viewed in the Z direction.

The pair of charge collection regions 252 face each other in the X direction with a portion of the charge generation region 251 on the surface 21a side interposed therebetween. Each charge collection region 252 is an n-type semiconductor region. Each charge collection region 252 functions as a charge accumulation region to which the charge generated in the charge generation region 251 is transferred as signal charge. An impurity concentration of each charge collection region 252 is, for example, about 1×10¹⁸ to 1×10²⁰ cm⁻³.

The charge collection regions 253 in one of the two pairs of charge collection regions 253 face each other in the X direction, with a portion on the surface 21a side in the charge generation region 251 interposed therebetween, on one side of the charge collection regions 252 in the pair in the Y direction. The charge collection regions 253 in the other of the two pairs of charge collection regions 253 face each other in the X direction, with the portion on the surface 21a side in the charge generation region 251 interposed therebetween, on the other side of the pair of charge collection regions 252 in the Y direction. Each charge collection region 253 is an n-type semiconductor region. Each charge collection region 253 functions as a charge discharge region to which the charge generated in the charge generation region 251 is transferred as discharge charge. An impurity concentration of each charge collection region 253 is, for example, about 1×10¹⁸ to 1×10²⁰ cm⁻³.

The photogate electrode 255 is disposed on a surface 251a of the charge generation region 251 on the light incidence side via an insulating film (not illustrated). The photogate electrode 255 is formed of a material (for example, polysilicon) having electrical conductivity and optical transparency to the near-infrared light L2. The photogate electrode 255 functions as an electrode that attracts the charge generated in the charge generation region 251. A shape of the photogate electrode 255 when viewed in the Z direction is, for example, a rectangular shape having long sides facing each other in the X direction and short sides facing each other in the Y direction.

The pair of transfer gate electrodes 256 are disposed on the surface 251a of the charge generation region 251 via an insulating film (not illustrated). The pair of transfer gate electrodes 256 face each other in the X direction with the photogate electrode 255 interposed therebetween. Each transfer gate electrode 256 is formed of a material (for example, polysilicon) that is conductive and optically transparent to the near-infrared light L2. Each transfer gate electrode 256 functions as an electrode that transfers charge attracted by the photogate electrode 255 to each adjacent charge collection region 252. A shape of each transfer gate electrode 256 when viewed in the Z direction is, for example, a rectangular shape having long sides facing each other in the X direction and short sides facing each other in the Y direction.

The two pairs of transfer gate electrodes 257 are disposed on the surface 251a of the charge generation region 251 via an insulating film (not illustrated). The transfer gate electrodes 257 in one of the two pairs of transfer gate electrodes 257 face each other in the X direction with the photogate electrode 255 interposed therebetween on one side of the pair of transfer gate electrodes 256 in the Y direction. The transfer gate electrodes 257 in the other of the two pairs of transfer gate electrodes 257 face each other in the X direction with the photogate electrode 255 interposed therebetween on the other side of the pair of transfer gate electrodes 256 in the Y direction. Each transfer gate electrode 257 is formed of a material (for example, polysilicon) that is conductive and optically transparent to the near-infrared light L2. Each transfer gate electrode 257 functions as an electrode that transfers charge attracted by the photogate electrode 255 to the adjacent charge collection region 253. A shape of each transfer gate electrode 257 when viewed in the Z direction is, for example, a rectangular shape having long sides facing each other in the X direction and short sides facing each other in the Y direction.

As illustrated in (a) and (b) of FIG. 3, a size of each second pixel when viewed in the Z direction is larger than a size of each first pixel when viewed in the Z direction. Each second pixel 25 overlaps at least one of the light passage portions 16 when viewed in the Z direction. In the present embodiment, in each second pixel 25, the charge generation region 251 overlaps with a pair of light passage portions 16 (a pair of light passage portions 16 arranged in the Y direction) when viewed in the Z direction, and each of the charge collection regions 252 and 253 overlaps each first pixel 15 when viewed in the Z direction.

An operation of the imaging device 1A configured as above will be described. First, a light source (not illustrated) that pulse-oscillates the near-infrared light L2 to a target object is prepared together with the imaging device 1A. From the light source, the near-infrared light L2 is pulse-oscillated toward the target object in each second period among first periods and second periods that are alternately repeated. In this state, in each first period, the signal readout unit 14 of the first optical sensor 10 accumulates charge in each first pixel 15 of the first optical sensor 10, and reads a second signal from each second pixel 25 of the second optical sensor 20. In each second period, the signal readout unit 14 of the first optical sensor 10 accumulates charge in each second pixel 25 of the second optical sensor 20, and reads a first signal from the first pixel 15 of the first optical sensor 10. The first signal is an electrical signal based on the charge generated in the embedded photodiode 151 in response to incidence of the visible light L1 and accumulated in the charge collection region 152. The second signal is an electrical signal based on the charge generated in the charge generation region 251 in response to the incidence of the near-infrared light L2 and accumulated in the pair of charge collection regions 252. It is possible to generate a distance image of the target object by reading the first signal and the second signal in this way.

An operation of the second optical sensor 20 will be described in greater detail. In each second pixel 25 of the second optical sensor 20, when a voltage is applied to the photogate electrode 255, depletion layers are generated in the respective charge generation regions 251 of the first portion 25a and the second portion 25b. In this state, when the near-infrared light L2 is incident on the charge generation regions 251 of the first portion 25a and the second portion 25b, electrons generated in response to the incidence of the near-infrared light L2 in the respective charge generation regions 251 of the first portion 25a and the second portion 25b move toward the photogate electrode 255 at high speed.

In each second pixel 25, a reset voltage is first applied to the two pairs of transfer gate electrodes 257 of each of the first portion 25a and the second portion 25b in each second period. The reset voltage is a positive voltage with a potential of the photogate electrode 255 as a reference. Accordingly, the electrons that have moved toward the photogate electrode 255 are discharged from the two pairs of charge collection regions 253 in each of the first portion 25a and the second portion 25b.

Subsequently, a pulse voltage signal is applied to one pair of transfer gate electrodes 256 in each of the first portion 25a and the second portion 25b. As an example, the pulse voltage signal applied to one of transfer gate electrodes 256 in the pair is a voltage signal in which a positive voltage and a negative voltage are alternately repeated with the potential of the photogate electrode 255 as a reference, and is a voltage signal having the same period, pulse width and phase as an intensity signal of the near-infrared light L2 pulse-oscillated from the light source. On the other hand, the pulse voltage signal applied to the other of the transfer gate electrodes 256 in the pair is the same voltage signal as the pulse voltage signal applied to one of the transfer gate electrodes 256 in the pair except that the phase is shifted by 180°.

Accordingly, in each of the first portion 25a and the second portion 25b, electrons that have moved toward the photogate electrode 255 are alternately transferred to the pair of charge collection regions 252 at high speed. The electrons accumulated in each of the pair of charge collection regions 252 in each second period are read as the second signal by the signal readout unit 14 of the first optical sensor 10. When the near-infrared light L2 pulse-oscillated from the light source and reflected by the target object is detected by the second optical sensor 20, a phase of the intensity signal of the near-infrared light L2 detected by the second optical sensor 20 is shifted according to a distance to the target object with respect to the phase of the intensity signal of the near-infrared light L2 pulse-oscillated from the light source. Therefore, it is possible to acquire information on the distance to the target object by reading the electrons accumulated in each of the charge collection regions 252 in the pair in each second period as the second signal.

As described above, in the imaging device 1A, in the second optical sensor 20 in the subsequent stage, each second pixel 25 includes the charge generation region 251, the pair of charge collection regions 252, the photogate electrode 255, and the pair of transfer gate electrodes 256. Accordingly, in each second pixel 25, the charge generated in the charge generation region 251 is attracted by the photogate electrode 255, and the attracted charge is transferred to each charge collection region 252 by each transfer gate electrode 256. Therefore, even when the charge generated in the charge generation region 251 is small in amount, the charge is transferred to each charge collection region 252 at high speed and reliably. Therefore, with the imaging device 1A, it is possible to improve the sensitivity of the second optical sensor 20 in the subsequent stage. The imaging device 1A is assumed to be used in a high-temperature environment such as a vehicle, and in such a case, an influence of dark current tends to be significant, but it is possible to suppress generation of the dark current because the embedded photodiode 151 is adopted in each first pixel 15 of the first optical sensor 10 in a preceding stage. With the imaging device 1A, it is possible to realize a distance measurement image sensor that can exhibit sufficient performance even in a harsh environment such as an in-vehicle, by combining the first optical sensor 10 as an image sensor capable of realizing signal detection with suppressed generation of dark current, with the second optical sensor 20 as a photogate-type distance measurement sensor capable of realizing high-speed and high-sensitivity signal detection.

In the imaging device 1A, a size of each second pixel 25 when viewed in the Z direction is larger than a size of each first pixel 15 when viewed in the Z direction. This makes it possible to improve the sensitivity of each second pixel 25, for example, as compared to a case in which the size of each second pixel 25 is the same as the size of each first pixel 15.

In the imaging device 1A, the first optical sensor 10 includes the plurality of light passage portions 16 disposed two-dimensionally, and each second pixel 25 overlaps at least one of the plurality of light passage portions 16 when viewed in the Z direction. This makes it possible to cause the near-infrared light L2 to be efficiently incident on the second pixel 25 via the light passage portion 16.

In the imaging device 1A, each light passage portion 16 includes the waveguide structure 161. This makes it possible to cause the near-infrared light L2 to be more efficiently incident on the second pixel via the waveguide structure 161.

In the imaging device 1A, the embedded photodiode 151 is formed of silicon, and the charge generation region 251 and the charge collection regions 252 and 253 are made of silicon. This makes it possible to easily manufacture the second optical sensor 20.

In the imaging device 1A, the first optical sensor 10 includes the first wiring layer 12 disposed on the side opposite to the light incidence side with respect to the plurality of first pixels 15 in the Z direction, the second optical sensor 20 includes the second wiring layer 22 disposed on the light incidence side with respect to the plurality of second pixels in the Z direction, and the second wiring layer 22 is electrically and physically connected to the first wiring layer 12. This makes it possible to achieve integration of a wiring structure in the imaging device 1A.

In the imaging device 1A, the first optical sensor 10 includes the signal readout unit 14, and the signal readout unit 14 reads the first signal from each first pixel 15 and reads the second signal from each second pixel 25. This makes it possible to share the signal readout unit 14.

In the imaging device 1A, the signal readout unit 14 accumulates charge in each first pixel 15 and reads a second signal from each second pixel 25 in the first periods among the first periods and the second periods that are alternately repeated, and accumulates charge in each second pixel 25 and reads the first signal from each first pixel 15 in the second periods. Accordingly, when the imaging device 1A is used together with the light source that emits the near-infrared light L2, the near-infrared light L2 is prevented from being emitted from the light source in the first period in which the charge is accumulated in the first pixels 15. This makes it possible to prevent the first signal output from each first pixel 15 from being influenced by the near-infrared light L2.

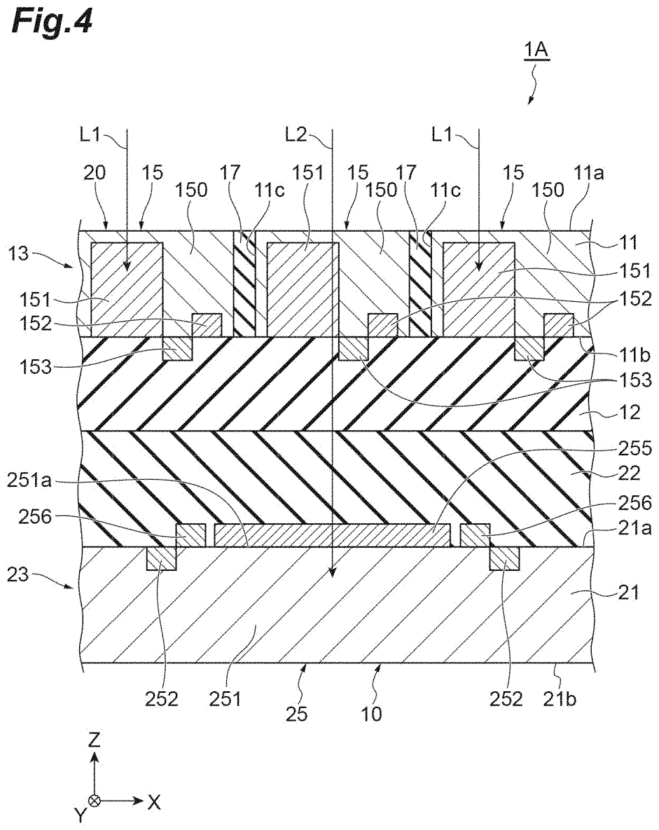

Further, the first pixel 15 may be provided instead of the light passage portion 16 in a portion in which the light passage portion 16 is provided in the first semiconductor layer 11 of the first optical sensor 10, as illustrated in FIG. 4. Also in this case, the near-infrared light L2 is transmitted through each first pixel 15 and is incident on each second pixel 25 of the second optical sensor 20. The first pixel 15 may be similarly provided instead of the light passage portion 16 in all embodiments and modification examples that will be described below.

Although the illustration of the p-type semiconductor region 151a and the n-type semiconductor region 151b is omitted in FIG. 4, even in the imaging device 1A illustrated in FIG. 4, the embedded photodiode 151 includes a p-type semiconductor region 151a and an n-type semiconductor region 151b, similarly to the imaging device 1A illustrated in FIG. 2.

### Second Embodiment

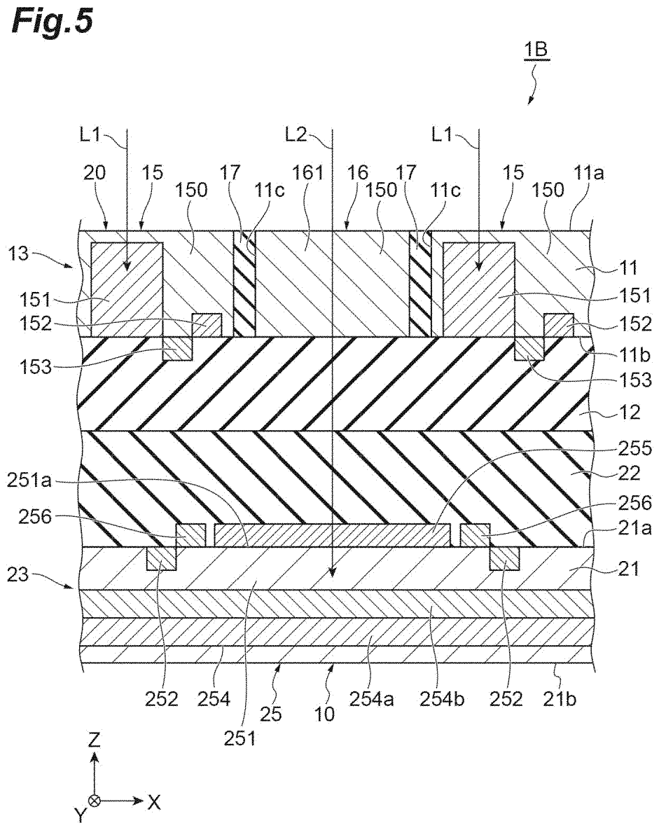

The imaging device 1B illustrated in FIG. 5 differs from the imaging device 1A described above in that each second pixel 25 of the second optical sensor 20 includes an avalanche multiplication region 254. As illustrated in FIG. 5, in the imaging device 1B, the charge generation region 251 includes the avalanche multiplication region 254 in each second pixel 25. The avalanche multiplication region 254 is formed to be positioned within the p-type semiconductor region in the charge generation region 251 of the imaging device 1A described above, and extends over the plurality of second pixels 25. The avalanche multiplication region 254 includes a first multiplication region 254a and a second multiplication region 254b. The first multiplication region 254a is a p-type semiconductor region on the surface 21b side. The second multiplication region 254b is an n-type semiconductor region on the surface 21a side. The first multiplication region 254a and the second multiplication region 254b form a pn junction. The avalanche multiplication region 254 is a region that causes avalanche multiplication. The avalanche multiplication region 254 can generate an electric field strength of 3×10⁵ to 4×10⁵ V/cm when a reverse bias having a predetermined value is applied. An impurity concentration of the first multiplication region 254a is, for example, 1×10¹⁶ cm⁻³ or more, and a thickness of the first multiplication region 254a is about 0.5 to 2.0 μm. An impurity concentration of the second multiplication region 254b is, for example, 1×10¹⁶ cm⁻³ or more, and a thickness of the second multiplication region 254b is about 0.5 to 2.0 μm. Although the illustration of the p-type semiconductor region 151a and the n-type semiconductor region 151b is omitted in FIG. 5, the embedded photodiode 151 in the imaging device 1B illustrated in FIG. 2 includes the p-type semiconductor region 151a and the n-type semiconductor region 151b, similarly to the imaging device 1A illustrated in FIG. 2.

With the imaging device 1B, it is possible to improve the sensitivity of the second optical sensor 20 in the subsequent stage, similarly to the imaging device 1A described above.

In the imaging device 1B, the charge generation region 251 includes the avalanche multiplication region 254. This makes it possible to further improve the sensitivity of the second optical sensor because the charge generated in the charge generation region 251 are avalanche-multiplied.

### Third Embodiment

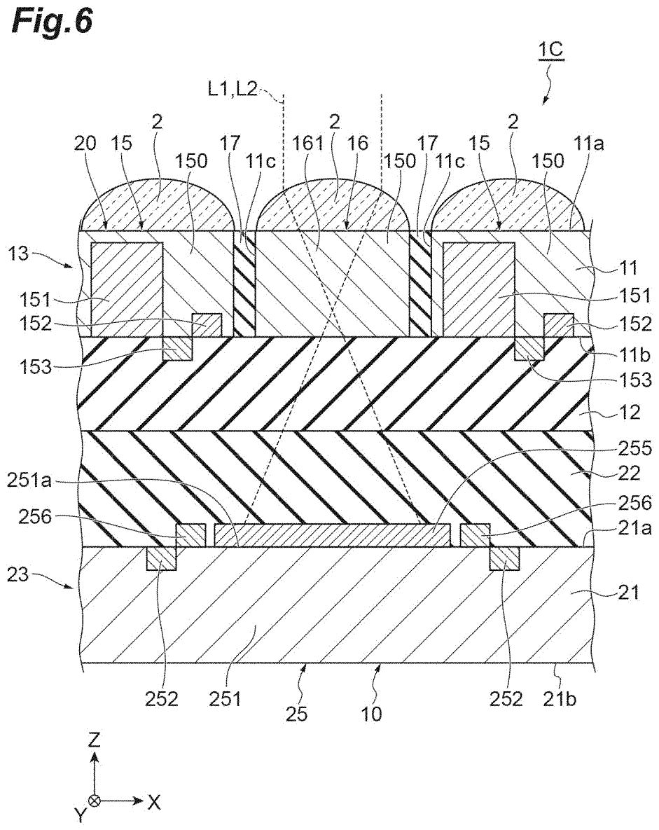

An imaging device 1C illustrated in FIG. 6 differs from the imaging device 1A described above in that the imaging device 1C includes a plurality of lenses 2. As illustrated in FIG. 6, the plurality of lenses 2 are disposed on the light incidence side with respect to the first optical sensor 10 in the Z direction to correspond to the plurality of first pixels 15 and the plurality of second pixels 25. Each lens 2 is disposed on the surface 11a of the first semiconductor layer 11 to overlap the first pixel 15 or the light passage portion 16 when viewed in the Z direction. Each lens 2 condenses the visible light L1 and the near-infrared light L2 within the first pixel 15 or within the light passage portion 16 (that is, within the first optical sensor 10). Although the illustration of the p-type semiconductor region 151a and the n-type semiconductor region 151b is omitted in FIG. 6, the embedded photodiode 151 in the imaging device 1C illustrated in FIG. 6 includes the p-type semiconductor region 151a and the n-type semiconductor region 151b, similarly to the imaging device 1A illustrated in FIG. 2.

With the imaging device 1C, it is possible to improve the sensitivity of the second optical sensor 20 in the subsequent stage, similarly to the imaging device 1A described above.

In the imaging device 1C, the plurality of lenses 2 are disposed on the light incidence side with respect to the first optical sensor 10 in the Z direction to correspond to the plurality of first pixels 15 and the plurality of second pixels 25, and each lens 2 condenses the visible light L1 and the near-infrared light L2 within the first optical sensor 10. Accordingly, the near-infrared light L2 is incident on each second pixel in a diverged state. In this case, because a size of each second pixel is larger than a size of each first pixel 15, it is possible for each second pixel 25 to efficiently receive the near-infrared light L2.

### Fourth Embodiment

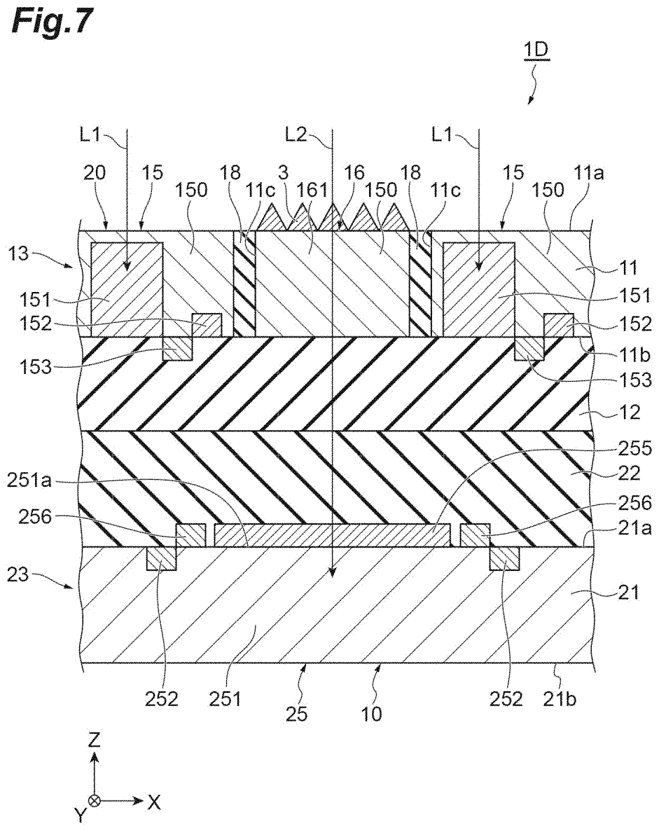

An imaging device 1D illustrated in FIG. 7 differs from the above-described imaging device 1A in that the imaging device 1D includes a plurality of texture structures 3. As illustrated in FIG. 7, the plurality of texture structures 3 are disposed to correspond to the plurality of second pixels 25, on the light incidence side with respect to the first optical sensor 10 in the Z direction. Each texture structure 3 is disposed on the surface 11a of the first semiconductor layer 11 to overlap the light passage portion 16 when viewed in the Z direction. The texture structure 3 is, for example, a layer made of silicon and is a layer in which unevenness of about 0.1 to 1.0 μm is formed on a surface by etching. In the imaging device 1D, a metal member 18 is disposed inside the trench 11c. The metal member 18 functions as a reflection portion that surrounds a region corresponding to each texture structure 3 (that is, the light passage portion 16) when viewed in the Z direction. Although the illustration of the p-type semiconductor region 151a and the n-type semiconductor region 151b is omitted in FIG. 7, the embedded photodiode 151 in the imaging device 1D illustrated in FIG. 7 includes the p-type semiconductor region 151a and the n-type semiconductor region 151b, similarly to the imaging device 1A illustrated in FIG. 2.

With the imaging device 1D, it is possible to improve the sensitivity of the second optical sensor 20 in the subsequent stage, similarly to the imaging device 1A described above.

In the imaging device 1D, the plurality of texture structures 3 are disposed to correspond to the plurality of second pixels 25 on the light incidence side with respect to the first optical sensor 10 in the Z direction, and the first optical sensor 10 includes the metal member 18 surrounding the region corresponding to each texture structure 3 when viewed in the Z direction. Accordingly, the near-infrared light L2 incident on the first optical sensor 10 at various angles while reflection is suppressed in the texture structure 3 is incident on the second pixel 25 at various angles while being reflected by the metal member 18. Further, a size of the second pixel 25 when viewed in the Z direction is larger than a size of the first pixel 15 when viewed in the Z direction. Therefore, an optical path of the near-infrared light L2 becomes longer in the second pixel 25, and the near-infrared light L2 is easily absorbed in the charge generation region 251 of the second pixel 25. This makes it possible for each second pixel 25 to efficiently receive the near-infrared light L2.

### Fifth Embodiment

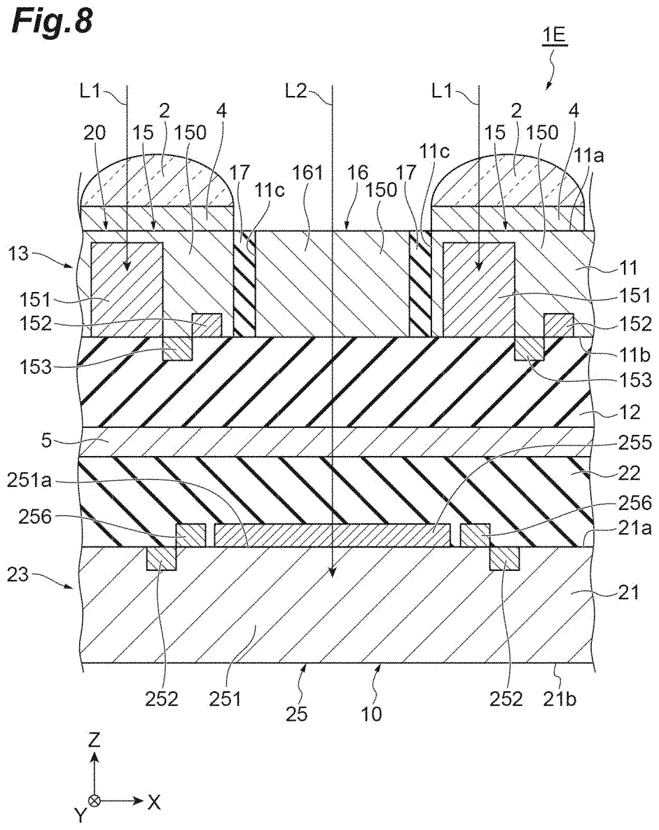

An imaging device 1E illustrated in FIG. 8 differs from the imaging device 1A described above in that the imaging device 1E includes a plurality of lenses 2, a plurality of color filters 4, and a band pass filter 5. As illustrated in FIG. 8, the plurality of color filters 4 are disposed on the light incidence side with respect to the first optical sensor 10 in the Z direction to correspond to the plurality of first pixels 15. Each color filter 4 is disposed on the surface 11a of the first semiconductor layer 11 to overlap the first pixels 15 when viewed in the Z direction. Each color filter 4 selectively transmits the visible light L1. That is, each color filter 4 cuts the near-infrared light L2. Although the illustration of the p-type semiconductor region 151a and the n-type semiconductor region 151b is omitted in FIG. 8, the embedded photodiode 151 in the imaging device 1E illustrated in FIG. 8 includes the p-type semiconductor region 151a and the n-type semiconductor region 151b, similarly to the imaging device 1A illustrated in FIG. 2.

The plurality of lenses 2 are disposed on the light incidence side with respect to the plurality of color filters 4 in the Z direction to correspond to the plurality of color filters 4. Each lens 2 is disposed on the color filter 4 to overlap the color filter 4 when viewed in the Z direction. Each lens 2 condenses the visible light L1 and the near-infrared light L2 within the first pixel 15 (that is, within the first optical sensor 10).

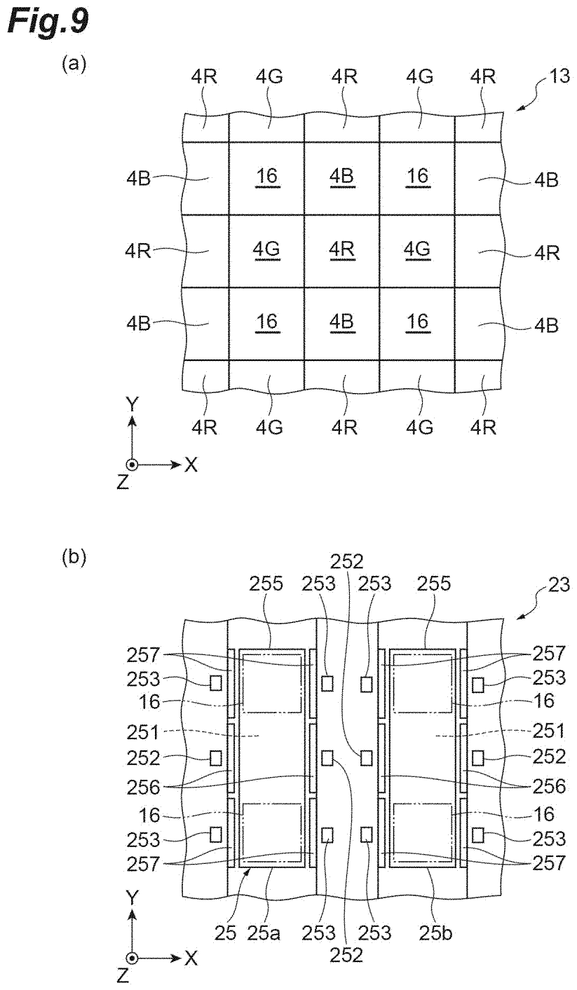

As illustrated in (a) of FIG. 9, the plurality of color filters 4 include a plurality of color filters 4R, 4G, and 4B. The plurality of color filters 4R selectively pass red light. The plurality of color filters 4G selectively pass green light. The plurality of color filters 4B selectively pass blue light. As an example, the plurality of color filters 4R are disposed so that the color filters 4R and the light passage portions 16 are alternately arranged in a “direction forming an angle of +45° with respect to the X direction” and a “direction forming an angle of −45° with respect to the X direction.” when viewed in the Z direction. The plurality of color filters 4G are disposed so that the color filters 4G and the light passage portions 16 are alternately arranged in the Y direction when viewed in the Z direction. The plurality of color filters 4B are disposed so that the color filters 4B and the light passage portions 16 are alternately arranged in the X direction when viewed in the Z direction.

As illustrated in (a) and (b) of FIG. 9, in each second pixel 25, each of the charge collection regions 252 and 253 corresponds to each color filter 4 (that is, each first pixel 15) when viewed in the Z direction. In the present embodiment, in each second pixel 25, the charge generation region 251 overlaps with a pair of light passage portions 16 (a pair of light passage portions 16 arranged in the Y direction) when viewed in the Z direction, and each of the charge collection regions 252 and 253 overlaps each color filter 4 (that is, each first pixel 15) when viewed in the Z direction. Illustration of the plurality of lenses 2 is omitted in (b) of FIG. 9.

As illustrated in FIG. 8, the band pass filter 5 is disposed between the first optical sensor 10 and the second optical sensor 20. The band pass filter 5 selectively transmits the near-infrared light L2. The band pass filter 5 includes, for example, a dielectric multilayer film.

With the imaging device 1E, it is possible to improve the sensitivity of the second optical sensor 20 in the subsequent stage, similarly to the imaging device 1A described above.

In the imaging device 1E, the plurality of color filters 4 are disposed to correspond to the plurality of first pixels 15, on the light incidence side with respect to the first optical sensor 10 in the Z direction, and each color filter 4 selectively transmits the visible light L1. This makes it possible to acquire an image of a target object using the visible light L1 on the basis of a signal output from the first optical sensor 10.

In the imaging device 1E, the plurality of lenses 2 are disposed to correspond to the plurality of color filters 4, on the light incidence side with respect to the plurality of color filters 4 in the Z direction, and each lens 2 condenses the visible light L1 within the first pixel 15. This makes it possible to more reliably acquire an image of a target object using the visible light L1.

In the imaging device 1E, the band pass filter 5 that selectively transmits the near-infrared light L2 is disposed between the first optical sensor 10 and the second optical sensor 20. This makes it possible to accurately detect the near-infrared light L2 in the second optical sensor 20.

In the imaging device 1E, each charge collection region 252 overlaps one of the plurality of first pixels 15 when viewed in the Z direction. This makes it possible to suppress the occurrence of parasitic sensitivity caused by incidence of the near-infrared light L2 on each charge collection region 252.

### Sixth Embodiment

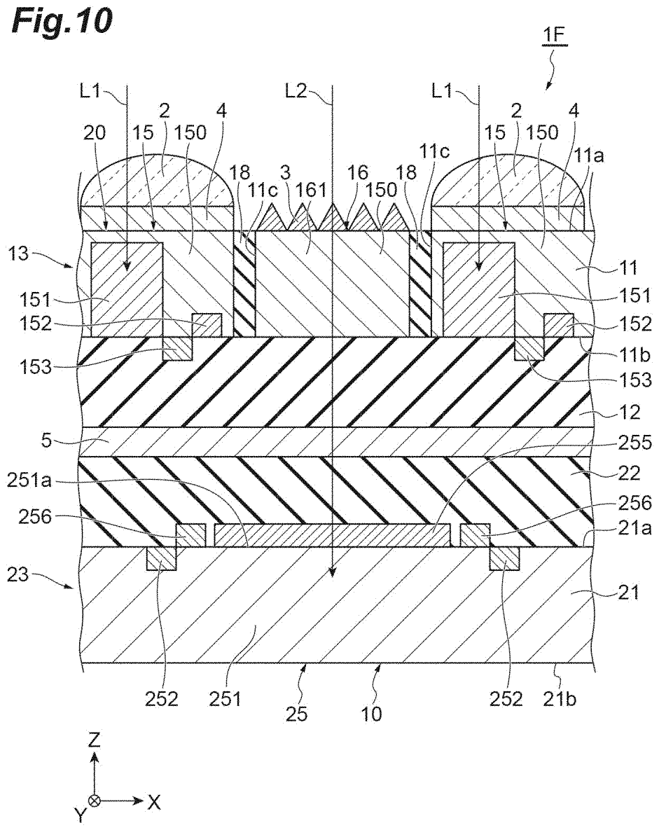

An imaging device 1F illustrated in FIG. 10 differs from the above-described imaging device 1E in that the imaging device 1F includes a plurality of texture structures 3. As illustrated in FIG. 10, the plurality of texture structures 3 are disposed to correspond to the plurality of second pixels 25, on the light incidence side with respect to the first optical sensor 10 in the Z direction. Each texture structure 3 is disposed on the surface 11a of the first semiconductor layer 11 to overlap the light passage portion 16 when viewed in the Z direction.

The texture structure 3 is, for example, a layer made of silicon and is a layer in which unevenness of about 0.1 to 1.0 μm is formed on a surface by etching. In the imaging device 1F, a metal member 18 is disposed inside the trench 11c. The metal member 18 functions as a reflection portion that surrounds a region corresponding to each texture structure 3 (that is, the light passage portion 16) when viewed in the Z direction. Although the illustration of the p-type semiconductor region 151a and the n-type semiconductor region 151b is omitted in FIG. 10, the embedded photodiode 151 in the imaging device 1F illustrated in FIG. includes the p-type semiconductor region 151a and the n-type semiconductor region 151b, similarly to the imaging device 1A illustrated in FIG. 2.

With the imaging device 1F, it is possible to improve the sensitivity of the second optical sensor 20 in the subsequent stage, similarly to the imaging device 1A described above.

In the imaging device 1F, the plurality of color filters 4 are disposed to correspond to the plurality of first pixels 15, on the light incidence side with respect to the first optical sensor 10 in the Z direction, and each color filter 4 selectively transmits the visible light L1. This makes it possible to acquire an image of a target object using the visible light L1 on the basis of a signal output from the first optical sensor 10.

In the imaging device 1F, the plurality of lenses 2 are disposed to correspond to the plurality of color filters 4, on the light incidence side with respect to the plurality of color filters 4 in the Z direction, and each lens 2 condenses the visible light L1 within the first pixel 15. This makes it possible to more reliably acquire an image of a target object using the visible light L1.

In the imaging device 1F, the band pass filter 5 that selectively transmits the near-infrared light L2 is disposed between the first optical sensor 10 and the second optical sensor 20. This makes it possible to accurately detect the near-infrared light L2 in the second optical sensor 20.

In the imaging device 1F, each charge collection region 252 overlaps one of the plurality of first pixels 15 when viewed in the Z direction. This makes it possible to suppress the occurrence of parasitic sensitivity caused by incidence of the near-infrared light L2 on each charge collection region 252.

In the imaging device 1F, the plurality of texture structures 3 are disposed to correspond to the plurality of second pixels 25 on the light incidence side with respect to the first optical sensor 10 in the Z direction, and the first optical sensor 10 includes the metal member 18 surrounding the region corresponding to each texture structure 3 when viewed in the Z direction. Accordingly, the near-infrared light L2 incident on the first optical sensor 10 at various angles while reflection is suppressed in the texture structure 3 is incident on the second pixel 25 at various angles while being reflected by the metal member 18. Further, a size of the second pixel 25 when viewed in the Z direction is larger than a size of the first pixel 15 when viewed in the Z direction. Therefore, an optical path of the near-infrared light L2 becomes longer in the second pixel 25, and the near-infrared light L2 is easily absorbed in the charge generation region 251 of the second pixel 25. This makes it possible for each second pixel 25 to efficiently receive the near-infrared light L2.

### Seventh Embodiment

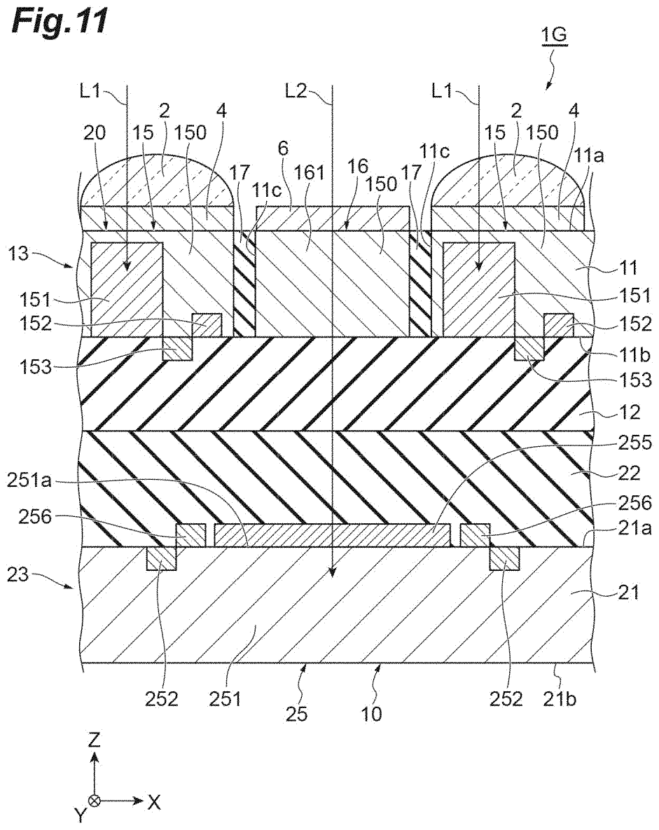

An imaging device 1G illustrated in FIG. 11 differs from the above-described imaging device 1E in that the imaging device 1G includes the plurality of plasmon filters 6 and does not include the band pass filter 5. As illustrated in FIG. 11, the plurality of plasmon filters 6 are disposed to correspond to the plurality of second pixels 25, on the light incidence side with respect to the first optical sensor 10 in the Z direction. Each plasmon filter 6 is disposed on the surface 11a of the first semiconductor layer 11 to overlap the light passage portion 16 when viewed in the Z direction. Each plasmon filter 6 selectively transmits the near-infrared light L2. The plasmon filter 6 is a film body having a plurality of nanoholes disposed two-dimensionally at a predetermined pitch. The predetermined pitch and a diameter of the nanoholes can be appropriately set according to a transmission wavelength. The predetermined pitch is, for example, 1 μm or less. The diameter of the nanohole is, for example, 1 μm or less. A material of the film body is, for example, gold or aluminum. Although illustration of the p-type semiconductor region 151a and the n-type semiconductor region 151b is omitted in FIG. 11, the embedded photodiode 151 in the imaging device 1G illustrated in FIG. 11 includes the p-type semiconductor region 151a and the n-type semiconductor region 151b, similarly to the imaging device 1A illustrated in FIG. 2.

With the imaging device 1G, it is possible to improve the sensitivity of the second optical sensor 20 in the subsequent stage, similarly to the imaging device 1A described above.

In the imaging device 1G, the plurality of color filters 4 are disposed to correspond to the plurality of first pixels 15, on the light incidence side with respect to the first optical sensor 10 in the Z direction, and each color filter 4 selectively transmits the visible light L1. This makes it possible to acquire an image of a target object using the visible light L1 on the basis of a signal output from the first optical sensor 10.

In the imaging device 1G, the plurality of lenses 2 are disposed to correspond to the plurality of color filters 4, on the light incidence side with respect to the plurality of color filters 4 in the Z direction, and each lens 2 condenses the visible light L1 within the first pixel 15. This makes it possible to more reliably acquire an image of a target object using the visible light L1.

In the imaging device 1G, the plurality of plasmon filters 6 are disposed to correspond to the plurality of second pixels 25, on the light incidence side with respect to the first optical sensor 10 in the Z direction, and each plasmon filter 6 selectively transmits the near-infrared light L2. This makes it possible to accurately detect the near-infrared light L2 in the second optical sensor 20.

In the imaging device 1G, each charge collection region 252 overlaps one of the plurality of first pixels 15 when viewed in the Z direction. This makes it possible to suppress the occurrence of parasitic sensitivity caused by incidence of the near-infrared light L2 on each charge collection region 252.

### Modification Example

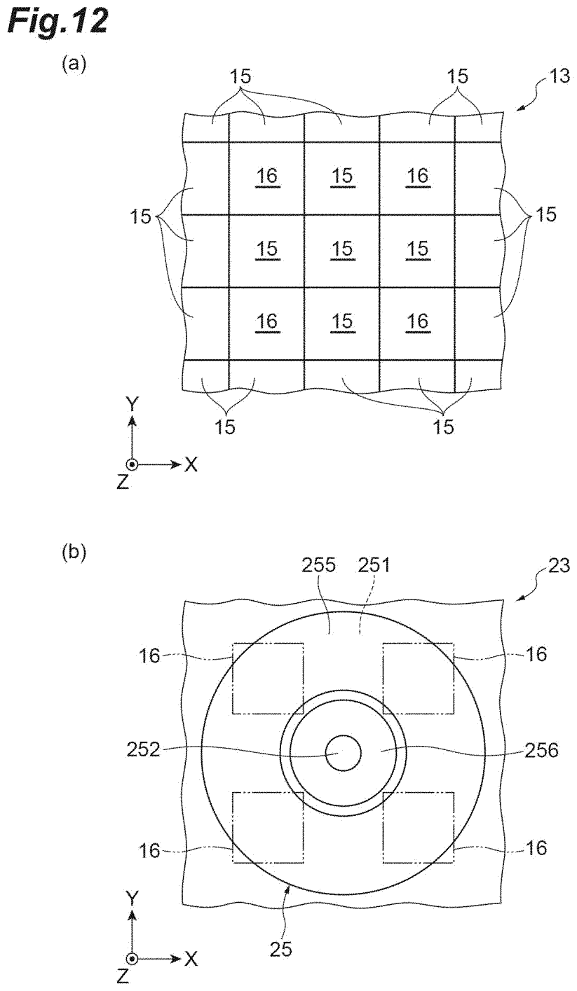

The present disclosure is not limited to the above embodiments. For example, the second pixel 25 may include the charge generation region 251 formed in an annular shape to overlap the four light passage portions 16 (four light passage portions 16 disposed in two rows and two columns) when viewed in the Z direction, as illustrated in (a) and (b) of FIG. 12. In the second pixel 25 illustrated in (a) and (b) of FIGS. 12, the charge collection region 252 is formed in a circular shape inside the charge generation region 251. The photogate electrode 255 is formed in an annular shape to overlap the charge generation region 251 when viewed in the Z direction. The transfer gate electrode 256 is formed in an annular shape to be positioned between the charge generation region 251 and the charge collection region 252 when viewed in the Z direction. In the second pixel 25 illustrated in (a) and (b) of FIG. 12, charge can be transferred to the charge collection region 252 at a first timing in a first frame and charge can be extracted from the charge collection region 252, and charge can be transferred to the charge collection region 252 at a second timing different from the first timing in a second frame different from the first frame and the charge can be extracted from the charge collection region 252.

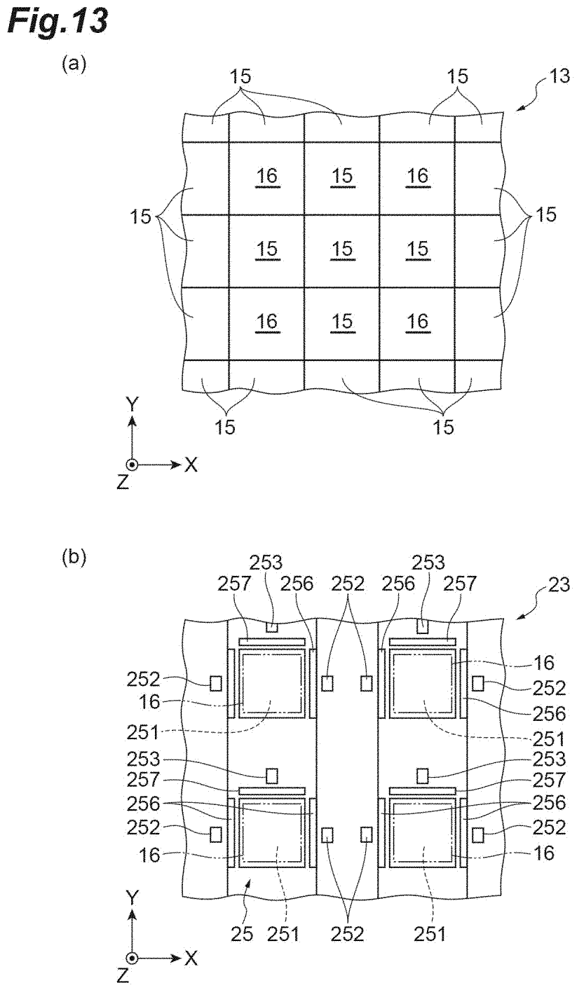

As illustrated in (a) and (b) of FIG. 13, the second pixel 25 may include four charge generation regions 251 disposed to overlap four light passage portions 16 (four light passage portions 16 disposed in two rows and two columns) when viewed in the Z direction. In the second pixel 25 illustrated in (a) and (b) of FIG. 13, a pair of charge collection regions 252 and a pair of transfer gate electrodes 256 corresponding to the pair of charge collection regions 252, and one charge collection region 253 and one transfer gate electrode 257 corresponding to the one charge collection region 253 are formed for each charge generation region 251. In the second pixel 25 illustrated in (a) and (b) of FIGS. 13, a pulse voltage signal is applied to a pair of transfer gate electrodes 256 corresponding to each charge generation region 251, similarly to the imaging device 1A described above. As an example, pulse voltage signals whose phases are shifted by 180° are applied to one and the other of transfer gate electrodes 256 in the pair. In the second pixel 25 illustrated in (a) and (b) of FIG. 13, the charge transferred to the one charge collection region 252 corresponding to each charge generation region 251 can be summed and taken out, and the charges transferred to the other charge collection region 252 corresponding to each charge generation region 251 can be summed and taken out.

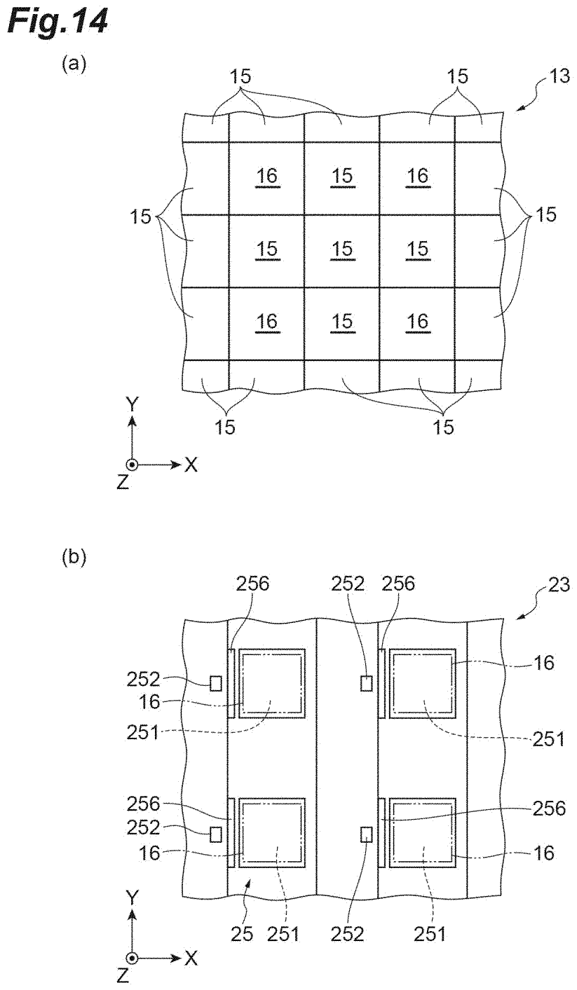

As illustrated in (a) and (b) of FIG. 14, the second pixel 25 may include four charge generation regions 251 disposed to overlap four light passage portions 16 (four light passage portions 16 disposed in two rows and two columns) when viewed in the Z direction. In the second pixel 25 illustrated in (a) and (b) of FIG. 14, one charge collection region 252 and a pair of transfer gate electrodes 256 corresponding to the one charge collection region 252 are formed for each charge generation region 251. In the second pixel 25 illustrated in (a) and (b) of FIG. 14, charge can be transferred to each charge collection region 252 at a first timing in a first frame and charge can be extracted from each charge collection region 252, and charge can be transferred to each charge collection region 252 at a second timing different the first timing in a second frame different from first frame and charge can be extracted from each charge collection region 252.

Each of the imaging devices 1A, 1B, 1C, 1D, 1E, 1F, and 1G is not limited to a device in which the first optical sensor 10 detects the visible light L1 and the second optical sensor 20 detects the near-infrared light L2, and may be a device in which the first optical sensor 10 detects the light in the first wavelength band and the second optical sensor 20 detects the light in the second wavelength band on the longer wavelength side relative to the first wavelength band. In this case, the entire second wavelength band may be shifted to the long wavelength side with respect to the first wavelength band, or a part of the second wavelength band may be shifted to the long wavelength side with respect to the first wavelength band. That is, when a center wavelength of the second wavelength band is shifted to the longer wavelength side with respect to a center wavelength of the first wavelength band, a part of the first wavelength band may overlap a part of the second wavelength band.

In the first pixel 15, the embedded photodiode 151 may be any type of photodiode as long as the embedded photodiode 151 is an embedded type. For example, the embedded photodiode 151 is not limited to a PN photodiode and may be a PIN photodiode, an APD, or the like.

In the second pixel 25, the charge generation region 251 and the charge collection regions 252 and 253 may be made of germanium. This makes it possible to further improve the sensitivity of the second optical sensor 20 to the near-infrared light L2.

In each of the imaging devices 1A, 1B, 1C, 1D, 1E, 1F, and 1G, the signal readout unit 14 may accumulate the charge in each first pixel and accumulate the charge in each second pixel 25 in the first periods among the first periods and the second periods that are alternately repeated, and read the first signal from each first pixel 15 and read the second signal from each second pixel 25 in the second periods. This makes it possible to associate distance information acquired by the second optical sensor 20 in the subsequent stage with the image acquired by the first optical sensor 10 in a preceding stage easily and accurately not only in terms of position but also in terms of time.

In each of the first optical sensor 10 and the second optical sensor 20, p-type and n-type conductivity types may be reversed with respect to those described above. Further, various materials and shapes can be applied to the respective configurations of the imaging devices 1A, 1B, 1C, 1D, 1E, 1F, and 1G described above, in addition to the materials and shapes described above. Further, each configuration in the embodiment or modification example described above can be arbitrarily applied to each configuration in other embodiments or modification examples.

### REFERENCE SIGNS LIST

1A, 1B, 1C, 1D, 1E, 1F, 1G Imaging device
2 Lens
3 Texture structure
4 Color filter
5 Band pass filter
6 Plasmon filter
10 First optical sensor
12 First wiring layer
14 Signal readout unit
15 First pixel
151 Embedded photodiode
16 Light passage portion
161 Waveguide structure
18 Metal member (reflection portion)
20 Second optical sensor
22 Second wiring layer
25 Second pixel
251 Charge generation region
252, 253 Charge collection region
254 Avalanche multiplication region
255 Photogate electrode
256, 257 Transfer gate electrode
L1 Visible light (light in first wavelength band)
L2 Near-infrared light (light in second wavelength band)

1: An imaging device comprising:
a first optical sensor configured to detect light in a first wavelength band; and
a second optical sensor disposed on the side opposite to the light incidence side with respect to the first optical sensor in an incidence direction of light, bonded to the first optical sensor, and configured to detect light in a second wavelength band on a longer wavelength side relative to the first wavelength band,
wherein the first optical sensor includes a plurality of first pixels disposed two-dimensionally along a first surface intersecting with the incidence direction,
the second optical sensor includes a plurality of second pixels disposed two-dimensionally along a second surface intersecting with the incidence direction,
each of the plurality of first pixels includes an embedded photodiode configured to generate charge in response to incidence of the light in the first wavelength band, and
each of the plurality of second pixels includes
a charge generation region configured to generate charge in response to the incidence of the light in the second wavelength band;
a charge collection region to which the charge generated in the charge generation region is transferred;
a photogate electrode configured to attract the charge generated in the charge generation region; and
a transfer gate electrode configured to transfer the charge attracted by the photogate electrode to the charge collection region.

2: The imaging device according to claim 1, wherein a size of each of the plurality of second pixels when viewed in the incidence direction is larger than a size of each of the plurality of first pixels when viewed in the incidence direction.

3: The imaging device according to claim 2, further comprising:
a plurality of lenses disposed to correspond to the plurality of first pixels and the plurality of second pixels, on the light incidence side with respect to the first optical sensor in the incidence direction, and configured to condense the light in the first wavelength band and the light in the second wavelength band within the first optical sensor.

4: The imaging device according to claim 2, further comprising:
a plurality of texture structures disposed to correspond to the plurality of second pixels, on the light incidence side with respect to the first optical sensor in the incidence direction,
wherein the first optical sensor further includes a reflection portion surrounding a region corresponding to each of the plurality of texture structures when viewed in the incidence direction.

5: The imaging device according to claim 1,
wherein the first optical sensor further includes a plurality of light passage portions disposed two-dimensionally along the first surface, and
each of the plurality of second pixels overlaps at least one of the plurality of light passage portions when viewed in the incidence direction.

6: The imaging device according to claim 5, wherein each of the plurality of light passage portions includes a waveguide structure.

7: The imaging device according to claim 1, wherein the charge generation region includes an avalanche multiplication region.

8: The imaging device according to claim 1, further comprising:
a plurality of color filters disposed to correspond to the plurality of first pixels, on the light incidence side with respect to the first optical sensor in the incidence direction, and configured to selectively transmit visible light, the visible light being the light in the first wavelength band.

9: The imaging device according to claim 8, further comprising:
a band pass filter disposed between the first optical sensor and the second optical sensor and configured to selectively transmit near-infrared light, the near-infrared light being the light in the second wavelength band.

10: The imaging device according to claim 8, further comprising:
a plurality of plasmon filters disposed to correspond to the plurality of second pixels, on the light incidence side with respect to the first optical sensor in the incidence direction, and configured to selectively transmit near-infrared light, the near-infrared light being the light in the second wavelength band.

11: The imaging device according to claim 8, wherein the charge collection region overlaps one of the plurality of first pixels when viewed in the incidence direction.

12: The imaging device according to claim 1,
wherein the embedded photodiode is formed of silicon, and
the charge generation region and the charge collection region are made of silicon.

13: The imaging device according to claim 1,
wherein the embedded photodiode is formed of silicon, and
the charge generation region and the charge collection region are made of germanium.

14: The imaging device according to claim 1,
wherein the first optical sensor further includes a first wiring layer disposed on the side opposite to the light incidence side with respect to the plurality of first pixels in the incidence direction,
the second optical sensor further includes a second wiring layer disposed on the light incidence side with respect to the plurality of second pixels in the incidence direction, and
the second wiring layer is electrically and physically connected to the first wiring layer.

15: The imaging device according to claim 14,
wherein the first optical sensor further includes a signal readout unit, and
the signal readout unit reads a first signal from each of the plurality of first pixels and reads a second signal from each of the plurality of second pixels.

16: The imaging device according to claim 15,
wherein the signal readout unit
causes charge to be accumulated in each of the plurality of first pixels and reads the second signal from each of the plurality of second pixels in first periods among alternately repeated first and second periods, and
causes charge to be accumulated in each of the plurality of second pixels and reads the first signal from each of the plurality of first pixels in the second periods.

17: The imaging device according to claim 15,
wherein the signal readout unit
causes charge to be accumulated in each of the plurality of first pixels and charge to be accumulated in each of the plurality of second pixels in first periods among alternately repeated first and second periods, and
reads the first signal from each of the plurality of first pixels and the second signal from each of the plurality of second pixels in the second periods.
